(19) United States
(12) Patent Application Publication
(10) Pub. No.: US 2020/0103733 A1
(43) Pub. Date: Apr. 2, 2020

(54) PROJECTION-TYPE DISPLAY APPARATUS

(71) Applicant: CANON KABUSHIKI KAISHA, Tokyo (JP)

(72) Inventor: Yuji Yoshiba, Utsunomiya-shi (JP)

(21) Appl. No.: 16/573,479

(22) Filed: Sep. 17, 2019

(30) Foreign Application Priority Data
Sep. 28, 2018 (JP) 2018-184601

(51) Int. Cl. G03B 21/16; G02F 1/1333; G03B 21/10; H05K 7/20

(52) U.S. Cl. CPC G03B 21/16; H05K 7/20663; G03B 21/10; G02F 1/1333

(57) ABSTRACT

A projection-type display apparatus includes a plurality of light modulating elements configured to modulate lights having wavelengths different from one another, a plurality of pipes corresponding respectively to the plurality of light modulating elements and configured to allow a refrigerant to be circulated, and a heat-dissipating member connected to the plurality of pipes and configured to dissipate heat from the plurality of light modulating elements through the refrigerant, the heat-dissipating member including a plurality of heat-dissipating regions corresponding respectively to the plurality of light modulating elements.

### BACKGROUND

### Field

The present disclosure relates to a projection-type display apparatus.

### Description of the Related Art

In a projection-type display apparatus such as a projector, the temperature of a light modulating element such as a liquid crystal display device at the time of use rises due to the incidence of a high intensity light from a light source. It is known moreover that modulation characteristics of a light modulating element are changed if the light modulating element is used at a temperature different from the temperature as set during production, leading to the deterioration of a projected image, namely, the flickering, unevenness or the like of the image. Accordingly, it is general to provide a projector with a cooling device so that a light modulating element of the projector can be used at a temperature falling within a specified range. In recent years, a laser light source has begun to be employed as a light source for a projector, and the light modulating element is required to be free of maintenance for a long period of time, as is the case with such light source. In order to make a light modulating element of a projector long-life, it is necessary to cool the light modulating element so as to actuate the light modulating element at a temperature lower than ever when the projector is used. As such a cooling device, a cooling system performing circulative cooling using a refrigerant is attracting attention.

In a projector, a plurality of light modulating elements is used, and it is known that such light modulating elements are different from each other in calorific value because the luminescence energy of light emitted from a light source varies according to the wavelength of the light. Japanese Patent No. 6015076 discusses an example of a liquid cooling system capable of cooling light modulating elements to a temperature falling within a specified range even if the optical modulators are different from each other in calorific value. Specifically, in the system as discussed, a heat pipe (heat conductive member) to feed fluid such as liquid to a light modulating element is provided for each of a plurality of light modulating elements, and heat from the light modulating elements is dissipated with a Peltier element (thermoelectric element) common to the heat pipes. It is discussed in the patent that the individual light modulating elements can be cooled to a temperature falling within a specified range by regulating the length, material, diameter or the like of the heat pipes so as to set a thermal resistance ratio among the heat pipes to a ratio among the reciprocals of the calorific values of the light modulating elements.

### SUMMARY

According to the method as discussed in Japanese Patent No. 6015076, however, a heat resistance will be raised if a light modulating element has a small calorific value, that is to say, it cannot be considered that an efficient heat dissipation is achieved with respect to the light modulating element. In order to carry out the cooling to a temperature falling within a desired range under a raised heat resistance condition, it would be required to increase the size of a thermoelectric element and enhance a revolution speed of a cooling fan to cool the thermoelectric element, which may increase the size of an apparatus or cause noise pollution.

In consideration thereof, the present disclosure features a projection-type display apparatus including a liquid cooling system capable of efficiently cooling a plurality of light modulating elements different from each other in calorific value to a temperature falling within a desired range.

A projection-type display apparatus according to an exemplary embodiment of the present disclosure includes a plurality of light modulating elements configured to modulate lights having wavelengths different from one another, a plurality of pipes corresponding to the plurality of light modulating elements, respectively, and configured to allow a refrigerant to be circulated, and a heat-dissipating member connected to the plurality of pipes and configured to dissipate heat from the plurality of light modulating elements through the refrigerant, the heat-dissipating member including a plurality of heat-dissipating regions corresponding to the plurality of light modulating elements, respectively.

Further features of the present disclosure will become apparent from the following description of exemplary embodiments with reference to the attached drawings.

### BRIEF DESCRIPTION OF THE DRAWINGS

FIG. 1 is a block diagram illustrating an optical system regarding a projector system as a projection-type display apparatus according to an exemplary embodiment of the present disclosure.

FIG. 2 is a schematic diagram illustrating a cooling device (cooling system) according to a first exemplary embodiment of the present disclosure.

FIG. 3 is an external view of a heat-dissipating member (radiator).

FIGS. 4A and 4B are diagrams illustrating a flow of a refrigerant in the heat-dissipating member (radiator).

FIGS. 5A and 5B are diagrams illustrating a positional relationship between the heat-dissipating member (radiator) and a cooling fan.

FIG. 6 is a schematic diagram illustrating a circulating liquid cooling system according to a second exemplary embodiment of the present disclosure.

### DESCRIPTION OF THE EMBODIMENTS

Exemplary embodiments of the present disclosure are described in detail below with reference to the accompanying drawings.

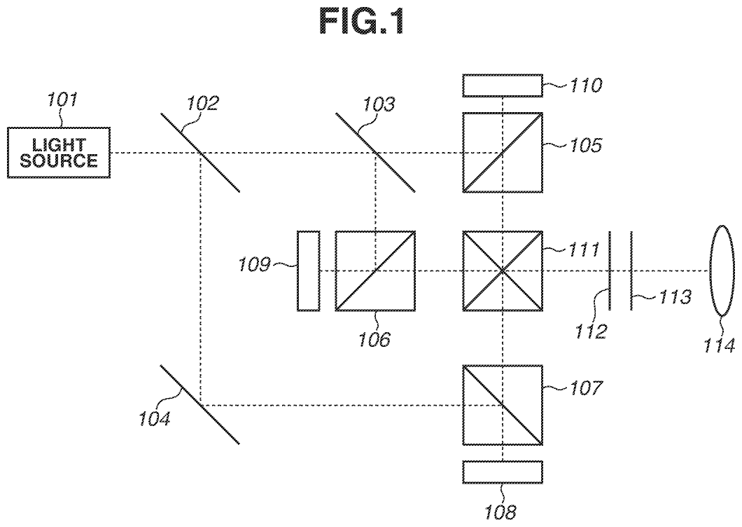

FIG. 1 is an example of a block diagram related to an optical system regarding a projector system as a projection-type display apparatus according to an exemplary embodiment of the present disclosure. The present disclosure is described here using a projector system including a reflective liquid crystal display device as a light modulating element, while the present disclosure is also applicable to a projector system using another type of light modulating element, such as a digital mirror device (DMD) or a transmissive liquid crystal display device. Specifically, the present disclosure is applicable to any projector system as long as a plurality of light modulating elements is included in the system. The projector system according to the present exemplary embodiment includes three light modulating elements. However, a projector system including more or less light modulating elements other than three light modulating elements can also be used for the present disclosure.

In FIG. 1, a projector system includes a light source 101, dichroic mirrors 102 and 103, a mirror 104, polarization beam splitters 105, 106 and 107, and liquid crystal display devices 108, 109 and 110.

The light source 101 is a light source emitting white light, and can be exemplified by an extra-high pressure mercury lamp, a xenon lamp, a laser, and a light emitting device (LED). The white light as emitted from the light source 101 is separated into a green component light (hereafter referred to as “component light G”) and a red-blue component light (hereafter referred to as “component light R-B”) by the dichroic mirror 102. In other words, separation is performed for each of specified wavelengths. The component light R-B is fed to the dichromic mirror 103 and separated into a component light R and a component light B.

The component lights G, R and B thus separated are fed to the polarization beam splitters 107, 106 and 105, respectively. The component lights G, R and B are fed from the polarization beam splitters 107, 106 and 105 to the liquid crystal display device 108 for green light, the liquid crystal display device 109 for red light, and the liquid crystal display device 110 for blue light, respectively.

The component lights G, R and B are controlled, according to input image signals, by the corresponding liquid crystal display devices 108, 109 and 110 with respect to the polarization, and returned to the polarization beam splitters 107, 106 and 105. Then, the component lights G, R and B are separated by the polarization beam splitters 107, 106 and 105, respectively, into the component light to be fed to an X prism 111 as a projection light and the component light to be returned toward the light source 101 depending on the state of polarization. The X prism 111 synthesizes the component lights G, R and B (projection lights) and feeds the synthetic light to a projection lens system 114. The projection lens system 114 projects the synthetic light thus fed onto a screen or the like to display an image.

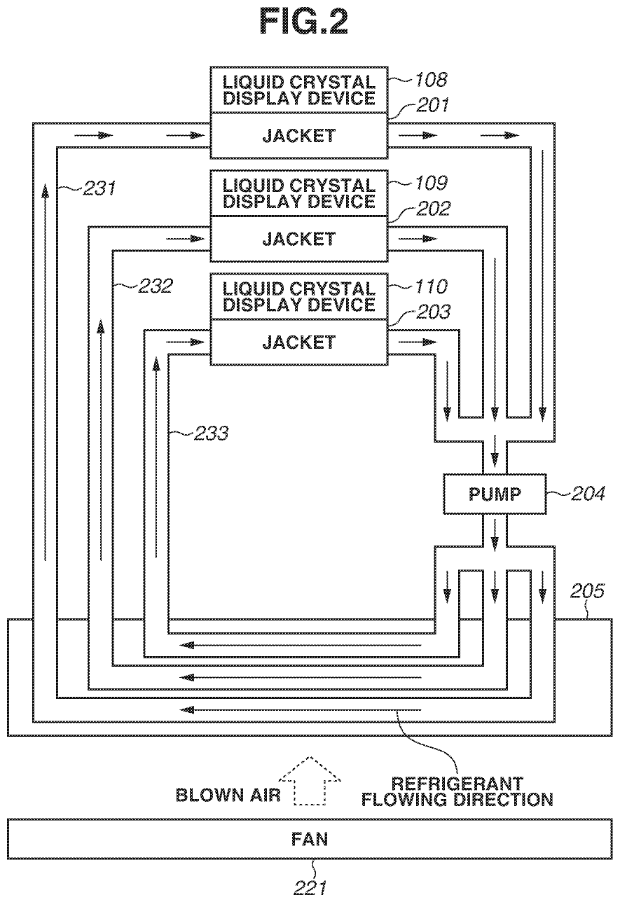

FIG. 2 is a schematic diagram illustrating a cooling device according to a first exemplary embodiment of the present disclosure. When the projector system operates, the liquid crystal display devices 108, 109 and 110 generate heat by absorbing an optical energy from the light source 101 and being actuated for modulation, and get high temperatures. In a case where a liquid crystal display device is actuated at a temperature higher than a target temperature as set during the production, a projected image suffers from flickering and unevenness, that is to say, the image quality is deteriorated, and the device in itself is deteriorated as well. Accordingly, cooling is performed so that the liquid crystal display device can be actuated at a temperature falling within a specified range. The cooling device according to the present exemplary embodiment is a circulative cooling system that cools the liquid crystal display devices 108, 109 and 110 by means of a refrigerant (liquid coolant). Exemplary refrigerants usable to the cooling device as above include such liquid as propylene glycol, while any refrigerant capable of cooling the liquid crystal display devices 108, 109 and 110 can be used.

The refrigerant as pushed out by the pressure of the pump 204 is distributed to three pipes that are provided for the liquid crystal display devices 108, 109 and 110, respectively. A pipe 231 connected to the liquid crystal display device 108 for green light allows part of the refrigerant to pass through a radiator 205 serving as a heat-dissipating member and to be then sent to a flow channel provided in a jacket 201 serving as a heat receiving section. A pipe 232 connected to the liquid crystal display device 109 for red light allows another part of the refrigerant to pass through the radiator 205 and to be then sent to a flow channel provided in a jacket 202. A pipe 233 connected to the liquid crystal display device 110 for blue light allows still another part of the refrigerant to pass through the radiator 205 and to be then sent to a flow channel provided in a jacket 203. The radiator 205 is provided with flow channels that correspond to the colors as associated with the liquid crystal display devices 108, 109 and 110, respectively, and the flow channels are provided so that the refrigerant can be cooled when passing through the flow channels. The radiator 205 is made of a metallic material, for which aluminum, iron or copper can be used. Opposite to a face of the radiator 205, a cooling fan 221 to cool the radiator 205 with blown air is arranged. The refrigerants coming out of the jackets 201, 202 and 203 are collected into one pipe and sent to the pump 204.

The jackets 201, 202 and 203 are provided on the liquid crystal display devices 108, 109 and 110, respectively, by face-bonding allowing thermal connection between the jackets 201, 202 and 203 and the liquid crystal display devices 108, 109 and 110, respectively. The jackets 201, 202 and 203 are made of a metallic material such as aluminum or copper, and provided with the flow channels, through which the refrigerant flows. In other words, the jackets 201, 202 and 203 each serve as a heat receiving section, and the fact that the refrigerant flows in the flow channels inside the jackets 201, 202 and 203 makes it possible to transfer the heat as generated by the liquid crystal display devices 108, 109 and 110 to the refrigerant. The refrigerant with the heat transferred thereto is cooled in the radiator 205 and used again to cool the liquid crystal display devices 108, 109 and 110.

In other words, the refrigerant is circulated through the pipes to pass through, starting from the pump 204, the radiator 205, the jackets 201, 202 and 203 (the liquid crystal display devices 108, 109 and 110), and the pump 204 in this order. The positional relationship among the pump 204, the radiator 205, and the jackets 201, 202 and 203 is not limited to that in FIG. 2, and any relative positions can be employed as long as the circulation of the refrigerant is possible.

In the present exemplary embodiment, the calorific value of the liquid crystal display devices 108, 109 and 110 at the time of use is such that the calorific value of the liquid crystal display device 108 for green light is the largest and the calorific value of the liquid crystal display device 110 for blue light is the next largest, while the calorific value of the liquid crystal display device 109 for red light is the smallest. The liquid crystal display devices 108, 109 and 110 can appropriately be changed in calorific value depending on the type of light source, because the difference between the calorific values as above is determined according to the light source 101 to be used.

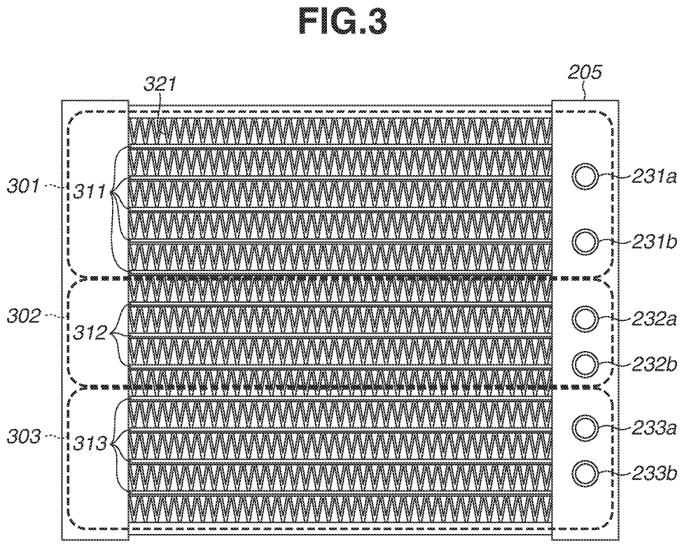

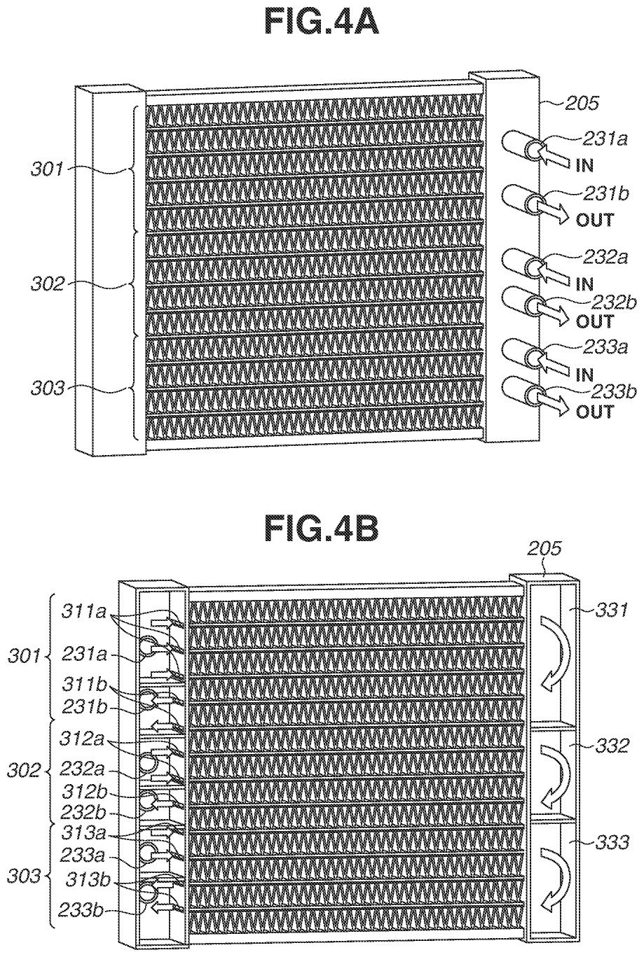

FIG. 3 is an external view of a radiator used as a heat-dissipating member according to an exemplary embodiment of the present disclosure. FIGS. 4A and 4B are diagrams illustrating the flow of the refrigerant in the radiator. FIG. 4A illustrates the radiator 205 from a side on which connectors are provided, and FIG. 4B illustrates the radiator 205 from a side opposite to the side in FIG. 4A. For better understanding's sake, flow channel walls are partially omitted.

As seen from FIG. 3, the radiator 205 is provided with connectors 231a and 231b to which the pipe 231 for green light is to be connected, connectors 232a and 232b to which the pipe 232 for red light is to be connected, and connectors 233a and 233b to which the pipe 233 for blue light is to be connected. The radiator 205 is divided into a heat-dissipation region 301 for cooling the refrigerant as sent through the pipe 231 for green light, a heat-dissipation region 302 for cooling the refrigerant as sent through the pipe 232 for red light, and a heat-dissipation region 303 for cooling the refrigerant as sent through the pipe 233 for blue light.

The heat-dissipation regions 301, 302 and 303 as illustrated in FIGS. 3, 4A and 4B are provided according to the calorific value of the liquid crystal display devices 108, 109 and 110 at the time of use. In the present exemplary embodiment, the above calorific value is such that the calorific value of the liquid crystal display device 108 for green light is the largest and the calorific value of the liquid crystal display device 110 for blue light is the next largest, while the calorific value of the liquid crystal display device 109 for red light is the smallest, so that the heat-dissipation region 301 for green light has the largest area, the heat-dissipation region 303 for blue light has the next largest area, and the heat-dissipation region 302 for red light has the smallest area. In other words, the heat-dissipation region 301 for green light is provided to be broader than either of the heat-dissipation region 303 for blue light and the heat-dissipation region 302 for red light, with the blue light and the red light each causing a smaller calorific value than the green light. Further, the heat-dissipation region 303 for blue light is provided to be broader than the heat-dissipation region 302 for red light, with the red light causing a smaller calorific value than the blue light. Such configuration enables the liquid crystal display devices 108, 109 and 110 to be each actuated at a temperature falling within an optimal range, even though the liquid crystal display devices 108, 109 and 110 have different calorific values depending on the color, which leads to an efficient heat dissipation. In a case where the pipes are different from one another in length depending on the color, it is beneficial to provide heat-dissipation regions taking a quantity of heat dissipated from the pipes into account. In the radiator 205 as illustrated in FIG. 3, the heat-dissipation region 301 for green light, the heat-dissipation region 302 for red light, and the heat-dissipation region 303 for blue light are aligned in this order from the top, while the order of alignment is not limited to this.

Referring to FIGS. 4A and 4B, the flow of the refrigerant in the radiator 205 is described. The refrigerant flowing into the radiator 205 through the connector 231a for the pipe 231 for green light is sent to three flow channels 311a of the heat-dissipation region 301 as three separate currents and, after the currents have been joined together in a liquid chamber 331, sent to two flow channels 311b of the heat-dissipating region 301, then to the pipe 231 through the connector 231b. The refrigerant flowing into the radiator 205 through the connector 232a for the pipe 232 for red light is sent to two flow channels 312a of the heat-dissipating region 302 as two separate currents and, after the currents have been joined together in a liquid chamber 332, sent to a flow channel 312b of the heat-dissipating region 302, then to the pipe 232 through the connector 232b. The refrigerant flowing into the radiator 205 through the connector 233a for the pipe 233 for blue light is sent to three flow channels 313a of the heat-dissipating region 303 as three separate currents and, after the currents have been joined together in a liquid chamber 333, sent to two flow channels 313b of the heat-dissipating region 303, then to the pipe 233 through the connector 233b. Between the flow channels of the heat-dissipating regions 301, 302 and 303, and the like, fins 321 are provided. The heat from the refrigerant is transferred to the fins 321 and dissipated into air by blowing air to the fins 321 by the cooling fan 221. In other words, the quantity of dissipated heat will be increased, in a case where the heat-dissipating regions 301, 302 and 303 are wider and the number of flow channels and the area of the fins 321 are accordingly increased.

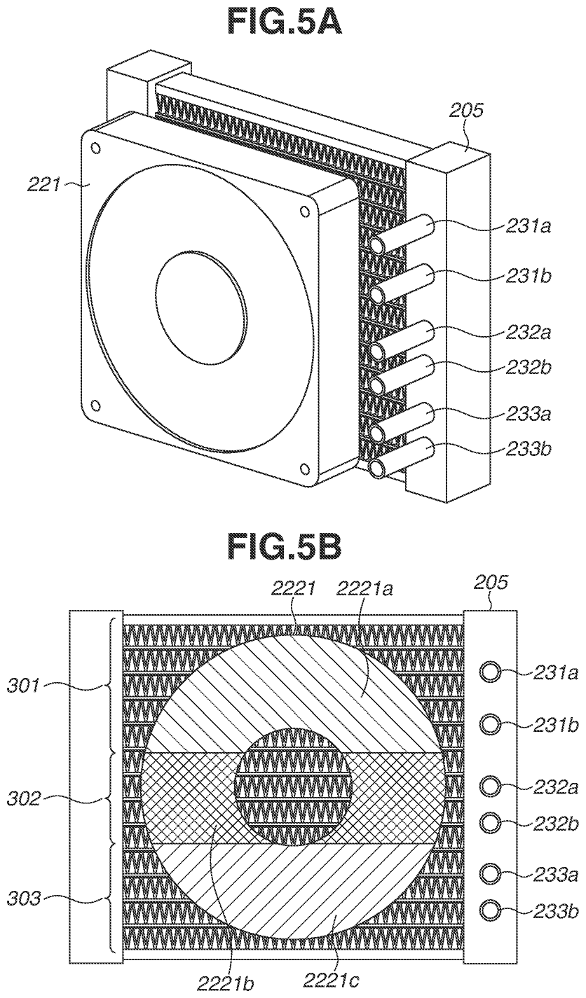

FIG. 5A is a diagram illustrating a positional relationship between the radiator 205 and the cooling fan 221. FIG. 5B is a diagram illustrating a positional relationship between a cooling region 2221 of the cooling fan 221 and the heat-dissipating regions 301, 302 and 303.

The cooling fan 221 is positioned to be opposite to a face where the fins 321 of the radiator 205 are arranged, and provided so that air can efficiently be blown to the heat-dissipating regions 301, 302 and 303. Specifically, the cooling fan 221 is provided so that air can perpendicularly be blown to the face where a plurality of flow channels 311, 312 and 313 is arranged.

On a rotation center of propellers of the cooling fan 221 as illustrated, a base, a shaft, and the like of a motor of the fan are provided, so that the shape of the rotation center allows no blades to be provided on the rotation center. In a region facing blades, a wind velocity and a cooling efficiency are both higher than those in any other regions. In other words, the cooling region 2221 as illustrated in FIG. 5B that faces the blades of the cooling fan 221 is a region with a high cooling efficiency, and the cooling efficiency varies depending on the location in such configuration.

Accordingly, an efficient heat dissipation can be achieved if an area ratio among a cooling region 2221a facing the heat-dissipating region 301, a cooling region 2221b facing the heat-dissipating region 302, and a cooling region 2221c facing the heat-dissipating region 303 is the same as an area ratio among the heat-dissipating regions 301, 302 and 303. For this reason, the cooling fan 221 is arranged in a position where such area ratio of the cooling regions 2221a, 2221b and 2221c can be realized. In other words, since the heat-dissipating region 301 has the largest area, the heat-dissipating region 303 has the next largest area, and the heat-dissipating region 302 has the smallest area, the cooling fan 221 is arranged so that the cooling region 2221a can have the largest area, the cooling region 2221c can have the next largest area, and the cooling region 2221b can have the smallest area. The arrangement of the cooling fan 221 based on the calorific value of the liquid crystal display devices 108, 109 and 110 as well makes it possible to achieve efficient cooling without the degradation of the cooling efficiency even if the calorific value of the liquid crystal display devices 108, 109 and 110 varies. Further, such arrangement can contribute to the downsizing of the circulative cooling system.

In the present exemplary embodiment, the cooling fan 221 is provided to cool the radiator 205. The cooling fan 221 may not be provided as far as exhaust heat from the fins 321 of the radiator 205 is sufficient and the liquid crystal display devices 108, 109 and 110 are cooled to a temperature falling within a specified range.

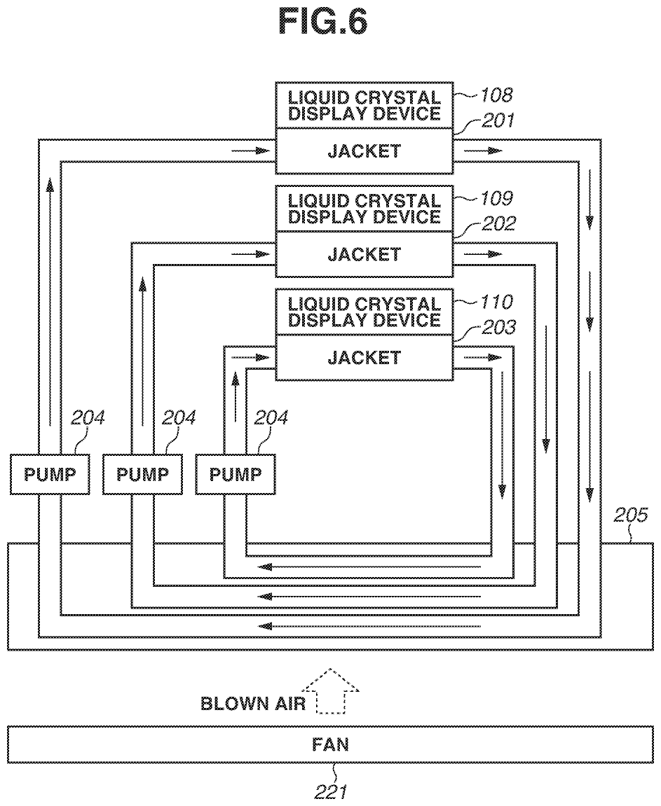

In the first exemplary embodiment as above, the pump 204 is made common to the liquid crystal display devices 108, 109 and 110 to achieve the downsizing of the cooling device. However, if it is possible to downsize the pump 204 in itself, the liquid crystal display devices 108, 109 and 110 can be provided with separate pumps 204, respectively, as illustrated in FIG. 6.

With respect to the configuration of the radiator 205 and other components, the second exemplary embodiment is the same as the first exemplary embodiment. Also in the second exemplary embodiment, the calorific value of the liquid crystal display device 108 for green light is the largest and the calorific value of the liquid crystal display device 110 for blue light is the next largest, while the calorific value of the liquid crystal display device 109 for red light is the smallest, so that the radiator 205 is separated into the heat-dissipating region 301 for green light that has the largest area, the heat-dissipating region 303 for blue light that has the next largest area, and the heat-dissipating region 302 for red light that has the smallest area. In other words, the heat-dissipating region 301 for green light is provided to be broader than either of the heat-dissipating region 303 for blue light and the heat-dissipating region 302 for red light, with the blue light and the red light each causing a smaller calorific value than the green light. Further, the heat-dissipating region 303 for blue light is provided to be broader than the heat-dissipating region 302 for red light, with the red light causing a smaller calorific value than the blue light. Such configuration enables the liquid crystal display devices 108, 109 and 110 to be each actuated at a temperature falling within an optimal range, even though the liquid crystal display devices 108, 109 and 110 have different calorific values depending on the color, which leads to an efficient heat dissipation.

While the present disclosure has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2018-184601, filed Sep. 28, 2018, which is hereby incorporated by reference herein in its entirety.

What is claimed is:

1. A projection-type display apparatus, comprising:
a plurality of light modulating elements configured to modulate lights having wavelengths different from one another;
a plurality of pipes corresponding respectively to the plurality of light modulating elements and configured to allow a refrigerant to be circulated; and
a heat-dissipating member connected to the plurality of pipes and configured to dissipate heat from the plurality of light modulating elements through the refrigerant, the heat-dissipating member including a plurality of heat-dissipating regions corresponding respectively to the plurality of light modulating elements.

2. The projection-type display apparatus according to claim 1, wherein a heat-dissipating region of the heat-dissipating member that corresponds to a light modulating element with a first calorific value among the plurality of light modulating elements is broader than a heat-dissipating region of the heat-dissipating member that corresponds to a light modulating element with a second calorific value smaller than the first calorific value among the plurality of light modulating elements.

3. The projection-type display apparatus according to claim 1, wherein the plurality of heat-dissipating regions of the heat-dissipating member has areas corresponding respectively to calorific values of the plurality of light modulating elements.

4. The projection-type display apparatus according to claim 1, wherein the heat-dissipating member is a radiator including a refrigerant flow channel provided for each of the plurality of light modulating elements.

5. The projection-type display apparatus according to claim 1, further comprising a pump connected to the plurality of pipes and configured to circulate the refrigerant.

6. The projection-type display apparatus according to claim 5, wherein the pump is provided in plurality to correspond respectively to the plurality of light modulating elements.

7. The projection-type display apparatus according to claim 1, further comprising a cooling fan configured to generate airflow toward the heat-dissipating member.

8. The projection-type display apparatus according to claim 7, wherein the cooling fan includes a plurality of cooling regions corresponding respectively to the plurality of heat-dissipating regions and is arranged with the plurality of cooling regions corresponding to calorific values of the plurality of light modulating elements.

9. The projection-type display apparatus according to claim 1, wherein the plurality of light modulating elements is each a liquid crystal display device.
